(19) United States
(12) Patent Application Publication
(10) Pub. No.: US 2009/0321056 A1
(43) Pub. Date: Dec. 31, 2009

(54) MULTI-STAGE ELECTROHYDRODYNAMIC FLUID ACCELERATOR APPARATUS

(75) Inventors: Hongyu Ran, Mountain View, CA (US); Yan Zhang, San Jose, CA (US); Kenneth Honer, Santa Clara, CA (US)

Correspondence Address: ZAGORIN O'BRIEN GRAHAM LLP (149), 7600B N. CAPITAL OF TX HWY, SUITE 350, AUSTIN, TX, 78731, US

(73) Assignee: Tessera, Inc., San Jose, CA (US)

(21) Appl. No.: 12/402,493

(22) Filed: Mar. 11, 2009

Related U.S. Application Data
(60) Provisional application No. 61/035,730, filed on Mar. 11, 2008.

(51) Int. Cl. H05K 7/20; F28D 15/00

(52) U.S. Cl. 165/104.34

(57) ABSTRACT

Multi-stage electrohydrodynamic (MHD) fluid flow acceleration is described. In some embodiments, an EHD fluid accelerator apparatus includes a substrate for thermal conduction and a plurality of electrode structures for thermal conduction therethrough, wherein each electrode structure has a collector electrode portion and a corona discharge electrode portion.

The present application claims priority under 35 U.S. C. 119(e) to U.S. Provisional Application 61/035,730 filed on Mar. 11, 2008 and entitled “Heat Sink Integrated with Ionic Flow Accelerator.”

### BACKGROUND

The subject matter of the present application is generally related to an electrohydrodynamic (also known as electro-fluid-dynamic) fluid accelerator apparatus that uses electrical fields to generate ions that produce a fluid flow, and more particularly, to an apparatus that utilizes corona discharge principles to move fluids (e.g., air molecules) in order to cool an electronic circuit.

Modern electronic devices contain more circuitry and components than earlier generations of these devices, causing them to generate additional heat that requires innovative cooling methods to maximize the operation and performance of the device. Examples of heat-generating components include, but are not limited to, integrated circuit (IC) chips, memory chips and various sensors that are components of electronic devices such as cell phones, laptop computers, personal digital assistance devices, desktop computers, and the like.

One type of cooling apparatus utilizes corona discharge principles to move fluids (e.g., air molecules) in order to cool electronic components using ambient air. A high electric field ionizes air molecules. The resulting ions are accelerated by the electric field and collide with neutral air molecules. During these collisions, momentum is transferred from the ionized gas to the neutral air molecules, resulting in a net movement of air towards a collector electrode. The ions are continually accelerated and collide with additional air molecules until they lose their charge, either to air molecules or to the collector electrode in their path.

### SUMMARY

Various embodiments of the cooling apparatus illustrated herein use an optimized aerodynamic fin/electrode arrangement to produce a compact electrohydrodynamic (EHD) fluid accelerator apparatus.

### BRIEF DESCRIPTION OF THE DRAWINGS

The structure and methods of fabrication of the EHD fluid accelerator apparatus described herein are best understood when the following description of several illustrated embodiments is read in connection with the accompanying drawings wherein the same reference numbers are used throughout the drawings to refer to the same or like parts. The drawings are not necessarily to scale; emphasis has instead been placed upon illustrating the structural and fabrication principles of the described embodiments. In the drawings,

FIG. 1 illustrates a elevational perspective side view of a first embodiment of an EHD fluid accelerator apparatus for use in cooling a component of an electronic device.

FIGS. 2A, 2B and 2C are top plan views of various embodiments of electrode structures that may be used in the EHD fluid accelerator apparatus;

FIG. 3 is a side elevation view of the formation of one embodiment of an electrode structure for use in the EHD fluid accelerator apparatus of FIG. 1;

FIG. 4 is a diagrammatic view of ion movement and fluid flow from an upstream electrode structure to a downstream electrode structure in the EHD fluid accelerator apparatus of FIG. 1;

FIGS. 5A and 5B diagrammatically illustrate variations of the electrode structures that may be used in the EHD fluid accelerator apparatus;

FIG. 6A diagrammatically illustrates fluid flow around the electrode structure of FIG. 5B;

FIG. 6C diagrammatically illustrates the concept of (a) a boundary layer formed by moving a fluid such as air over a hot surface, and (b) boundary layer enhancement that may be achieved by using the electrode structure of FIG. 5B;

FIG. 7 is a diagram of the fabrication steps for fabrication the EHD fluid accelerator apparatus of FIG. 1;

FIG. 8 is a flow diagram of the fabrication steps illustrated in FIG. 7; and

FIGS. 9A and 9B schematically illustrate first and second modes of operation of the EHD fluid accelerator apparatus of FIG. 1.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

### DETAILED DESCRIPTION

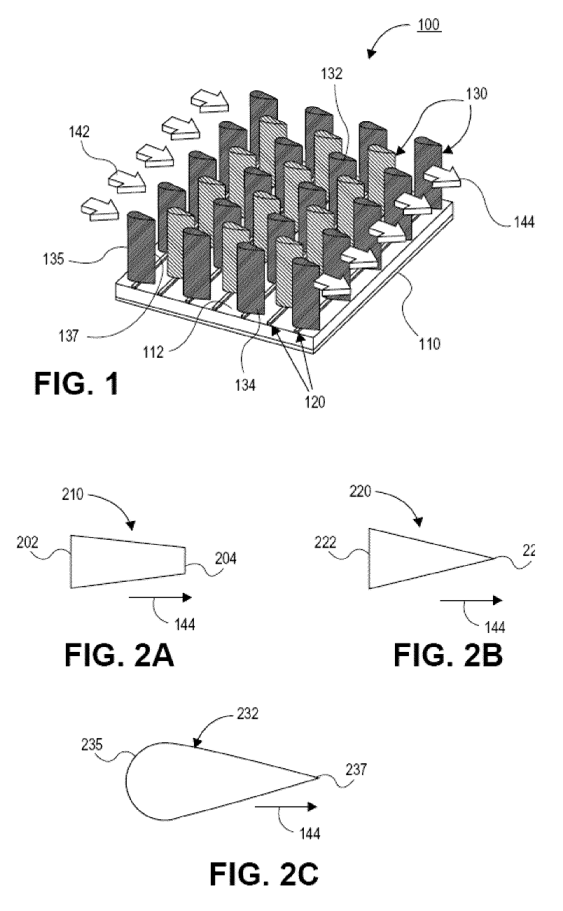

FIG. 1 illustrates an elevational perspective side view of EHD fluid accelerator apparatus 100 that includes substrate 110 having a top surface 112 on which is disposed a set 120 of electrical conductors. In one embodiment, substrate 110 may be a dielectric substrate made of ceramic or other suitable material. In another embodiment, substrate 110 may be a made of a high k ceramic. Substrate 110 may have a relative dielectric constant of 10. Substrate 110 may have any desired shape suitable for its intended purpose. In one embodiment, substrate 110 may be a square shape in the range of 10 centimeters (i.e., approximately four inches) on each side, but it is understood that the dimensions of substrate 110 may be selected to meet the cooling needs of the heat-generating component to which it is mated. In one embodiment, substrate 110 may have a thickness of 2.5 centimeters (i.e., approximately one inch).

A set 130 of electrode structures 132 are attached to top surface 112 of substrate 110. Each electrode structure 132 has a narrow side edge 137 and an opposing broad side edge 135, and may be oriented in the same direction on substrate 110, with narrow side edge 137 of electrode structure 132 being oriented on substrate 110 toward the intended direction of the flow of heated air, as represented by arrows 144. In one embodiment, set 130 of electrode structures 132 may be made of copper or some other suitable electrical conductor. In another embodiment, set 130 of electrode structures 132 may be made of a high thermal conductivity material to improve efficiency. A high thermal conductivity material may diminish thermal spreading resistance from the localized heat source to electrode structure 132 and may improve heat transfer by increasing temperature uniformity along electrode structures 132.

Base 134 of each electrode structure 132 makes contact with a portion of set 120 of electrical conductors, which receives an electric current to apply voltage to selected ones of electrode structures 132. Thus, set 120 of electrical conductors may have any suitable pattern on top surface 112 so as to make contact with base 134 of each electrode structure 132. In FIG. 1, set 120 of electrical conductors is shown as a series of evenly-spaced parallel metalized lines, but it is understood that another pattern may be suitable to provide voltage to base 134 of electrode structure 132.

In operation, ambient air represented by arrows 142 is directed to the broad edge of each electrode structure 132 and heated air is carried in the direction represented by arrows 144. In one embodiment, the ambient air flow across cooling apparatus 100 may be assisted by any type of conventional fan, which is not shown in FIG. 1.

Electrode structure 132 may encompass any three-dimensional shape in which the width of one side edge is narrower than the width of the opposing side edge. FIGS. 2A, 2B and 2C illustrate top plan views of exemplary structures 210, 220 and 132, respectively. In FIG. 2A, structure 210 has broad side edge 202 and narrow side edge 204. In FIG. 2B, structure 220 has broad side edge 222 and narrow side edge 224 which comes to a sharp point. In FIG. 2C, structure 232 resembles an airfoil shape and has broad side edge 235 and narrow side edge 237 which also comes to a sharp point. Note that in each of FIGS. 2A, 2B and 2C, each structure is oriented with its narrow side edge toward air flow direction 144. In addition, other structures, not shown in the figures, may be desirable in certain embodiments, such as straight fins, cubic pin fins, pyramids, dimples, and porous tunnels.

With reference again to the embodiment of cooling apparatus 100 of FIG. 1, electrode structures 132 may be disposed in evenly spaced rows on top surface 112 with the narrow side edge 137 of each electrode structure 132 facing toward direction 144. For example, the embodiment of cooling apparatus 100 of FIG. 1 shows seven rows of structures with their narrow side edges 137 facing direction 144. It is understood that FIG. 1 is representative of only one embodiment of the disposition of the structures on substrate 110. For example, in another embodiment, electrode structures 132 may be disposed in evenly spaced rows with 2.0 mm spacing between structures in each row; if substrate 110 is 10 centimeters (approximately four inches) wide, then cooling apparatus 100 would comprise more electrode structures 132 in each row than shown in FIG. 1.

In addition, adjacent evenly spaced rows of electrode structures 132 may be offset from one another. That is, if the seven rows of structures are numbered from one to seven proceeding from direction 142 to direction 144, then the narrow side edge 137 of a electrode structure 132 disposed in the first row confronts the broad side edge 135 of a electrode structure 132 disposed in the third row, and does not confront a broad side edge 135 of a electrode structure 132 in the row immediately in front of it. The term “downstream structure” refers to the relationship between a second electrode structure 132 disposed in a row that is closer to fluid flow direction 144 than a first electrode structure 132. Staggered or offset structures may aid in creating vortices to enhance air mixing and reduce air flow resistance. The effective convection coefficient for staggered electrode structures 132 with rounded broad side edges 135 may be a factor of 2.8 higher than in-line (i.e., not offset) electrode structures 132 with a more rectangular shaped broad side edge 135, such as that illustrated in FIG. 2B.

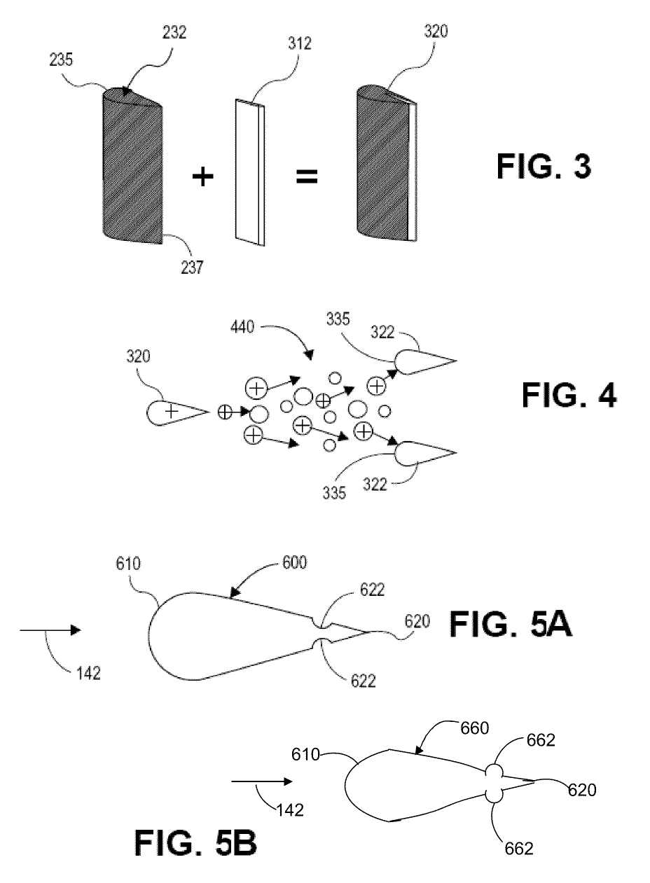

FIG. 3 illustrates an embodiment of electrode structure 132 in which structure 232 of FIG. 2C has sharp blade structure 312 inserted into narrow end 237 to produce structure 320.

As noted above, in EHD fluid accelerator technology, an electric field assists ion acceleration of fluid flow. Electrode structure 320 (FIG. 3) and the variations thereof illustrated herein may serve as both corona discharge electrodes and collector electrodes. In FIG. 3, the portion of structure 320 with sharp blade 312 serves as the corona discharge electrode, which, as illustrated in FIG. 4, generates ion stream 440. Ion stream 440 migrates toward downstream structures 322, the broad side edges 335 of which serve as collector electrodes.

In another embodiment of the EHD apparatus illustrated herein, structures 600 as shown in FIG. 5A and structures 660 as shown in FIG. 5B may be used as electrode structures. Structure 600, which may be a variation of structure 320 of FIG. 3, has intrusions 622 near the corona discharge electrode 620 portion of the structure and away from collector electrode portion 610 of the structure. Structure 660, which may also be a variation of structure 320 of FIG. 3, has protrusions 662 near the corona discharge electrode 620 portion of the structure and away from collector electrode portion 610 of the structure. Airfoil-shaped structures 600 and 660 both facilitate a more streamlined air flow and reduces drag.

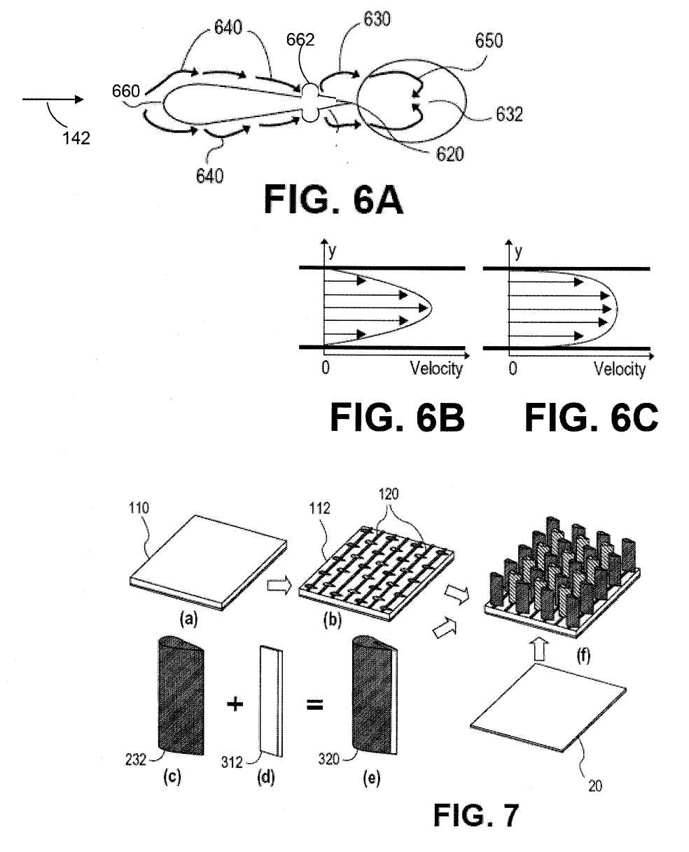

As illustrated in FIG. 6A, dust follows the streamlined air flow, as represented by arrows 640, around electrode structure 660, but will separate from the air flow when there is a perturbation in the shape of electrode structure 660, such as protrusion 662 in the sidewalls of structure 660. The airfoil shape is designed to cause boundary layer enhancement near narrow side edge 620, and a perturbation in the shape, illustrated in FIGS. 5A as intrusions 622 or as protrusions 662 in FIG. 5B, may trigger such boundary layer enhancement. In the case of structure 660, the detached air flow, as represented by arrows 630, carries dust away from the surface of electrode structure 660, protecting the corona electrode portion 620 of structure 660 from dust settlement thereon. Moving air, as represented by arrows 650, flows in the reverse direction in recirculation region 632 but dust particles of sufficient mass entrained in the air flow do not circulate back to corona electrode portion 620.

The concept of boundary layer enhancement is illustrated in FIG. 6B. The portion of the figure labeled (a) shows the typical parabolic curve generated for typical pressure differential (e.g., fan-driven) air flow, with velocity of ambient air flow on the x-axis across the surface of a heat sink, with the y-axis showing the distance from the surface. The air flow forms a boundary layer due to a no-slip boundary condition close to the hot surface of the substrate being cooled. Inside the boundary layer, air flow velocity is almost zero. Since heat is dissipated through conduction within the air there is a low convection coefficient.

Ionic fluid accelerator driven air flow is accelerated by the electrical field near the substrate surface resulting in a higher horizontal air flow velocity, as shown in the portion of the figure labeled (b). The air flow impinges on the surface, reduces the boundary layer thickness, and enhances heat transfer. It can be seen from graph (b) that air flow increases closer to the surface of the substrate. Thus, the Ionic flow reduces the boundary layer, enhancing heat transfer along entire length of heatsink and reducing back pressure.

### Method of Fabrication

FIG. 7 illustrates a diagrammatic flow of the fabrication of the EHD fluid accelerator apparatus described herein. FIG. 7 shows, in the portion labeled (a), an electrically insulating but highly thermally conductive substrate 110 with a coefficient of thermal expansion (CTE) preferably matched to the electronic component or circuit being cooled, In the portion labeled (b) of FIG. 7, patterned metal traces 120 that provide voltage to selective ones of the electrode structures are deposited on top surface 112 of substrate 110. In the portions labeled (c), (d) and (e) of FIG. 7, high-k electrode structures 232 are machined to the desired airfoil shape and a sharp blade structure 312 is bonded into a cutout of each electrode structure 232 to produce electrode structures 320. Electrode structures 320 are then connected to substrate 110. Optionally, in the portion labeled (f) of FIG. 7, completed EHD fluid accelerator apparatus 100 is bonded to an electronic component 20, and functions as an integrated air blower and heat sink.

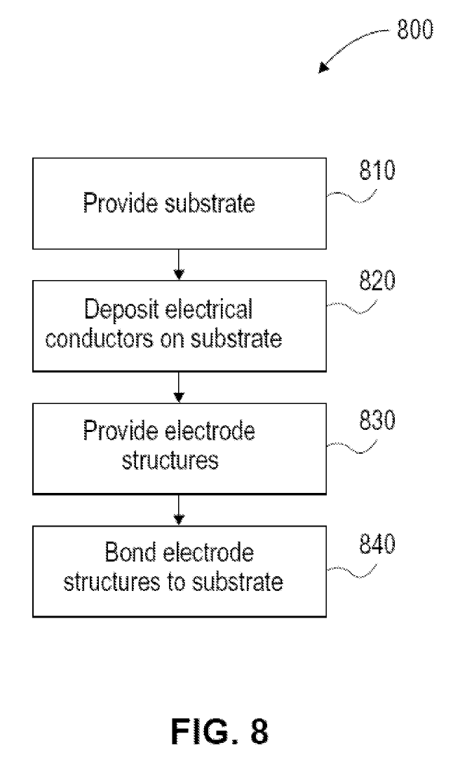

FIG. 8 illustrates flow diagram 800 of the basic fabrication steps used to produce the EHD fluid accelerator apparatus described herein. A substrate is provided in fabrication step 810, and electrical conductors are patterned on the substrate in fabrication step 820. Electrode structures such as structures 320 in FIG. 7 are then provided in fabrication step 830, for bonding to the substrate in fabrication step 840.

### Operational and Design Characteristics

The EHD fluid accelerator apparatus illustrated herein in its various embodiments is a multi-stage device. In a typical multi-stage device, each individual EHD device stage may be operated simultaneously and synchronously with the others in order to produce increased volume and pressure of fluid flow in the desired direction, thereby sequentially accelerating a fluid through the multiple stages. Synchronous operation of a multi-stage EHD device is defined herein to mean that a single power supply, or multiple synchronized and phase-controlled power supplies, provide high voltage power to each EHD device stage such that both the phase and amplitude of the electric power applied to the same type of electrodes in each stage (i.e., the corona discharge electrodes or the collector electrodes) are aligned in time. U.S. Pat. No. 6,727,657, entitled “Electrostatic Fluid Accelerator for and a Method of Controlling a Fluid Flow” provides a discussion of the configuration and operation of several embodiments of a multi-stage EHD device, including computing an effective inter-stage distance and exemplary designs for a high voltage power supply for powering neighboring EHD device stages with respective synchronous and syn-phased voltages. U.S. Pat. No. 6,727,657 is incorporated by reference herein in its entirety for all that it teaches.

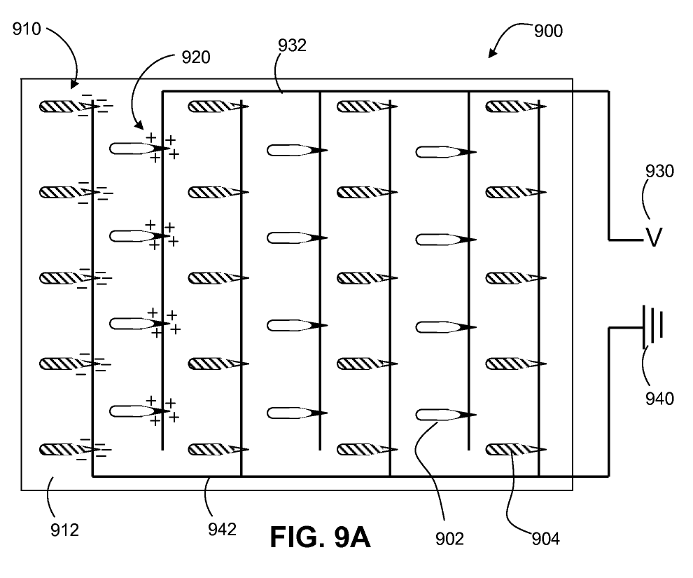

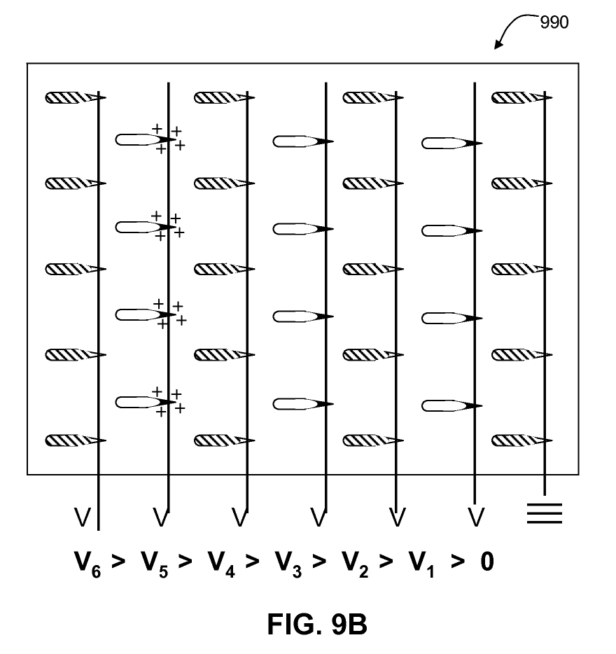

The multi-stage EHD device described herein may be powered by a high voltage power supply to operate in one of two modes of operation: (1) in an alternating voltage mode as shown in FIG. 9A; or (2) in a cascading voltage mode as shown in FIG. 9B. The alternating voltage method of operation schematically illustrated in FIG. 9A utilizes alternating rows 920 and 910 of high-voltage-powered electrode structures 902 and grounded electrode structures 904, or their alternative embodiments as described herein, that generate positively and negatively charged ions, respectively. High voltage power supply 930 connects electrodes in rows 920 via conductor 932. Ground 930 connects electrodes in rows 910 via conductor 932. Plus and minus signs indicate the polarity of the ions each electrode structure produces.

In the cascading voltage method of operation schematically illustrated in FIG. 9B, the neighboring rows of electrodes have a prescribed voltage difference that will accelerate the positive ions in a linear multi-stage fashion.

The two modes of operation provide a trade-off between voltage converter efficiency and the relatively simple implementation of the alternating voltage mode of FIG. 9A, and the overall ionic-driven air flow efficiency of the cascade voltage mode of operation illustrated in FIG. 9B. It is to be understood, however, that either mode of operation contributes to overall system efficiency.

Several factors optimize fluid flow, such as reducing the flow resistance, enhancing the turbulence and mixing of the fluid flow, and improving the cooling efficiency of the fluid flow. In the EHD apparatus described herein, the design parameters of particular interest in optimizing fluid flow are electrode structure shape and spacing. Fluid flow optimization may also be coupled with electric field optimization because the fluid flow is partially driven by the electric field.

Computational fluid dynamics (CFD) simulations may be used to provide insights as to the effect of ionic forcing and detailed information of the heat convection within the boundary layer. The electrode structures will be referred to as fins in this description. The fin efficiency η_{fin}, is a measure of the temperature uniformity from fin base to tip. To keep η_{fin} near 1.0, the value of H_{f}\sqrt{2h/k_{fin}t_{fin}} needs to be small, where H_{f} is fin height, h is the average convection coefficient of the EHD apparatus, k_{fin}, is the thermal conductivity of the fin, and t_{fin} the fin thickness. When the fins have a fixed fin height H_{f} and fin thickness t_{fin}, then k_{fin} has to increase with h. Materials with high thermal conductivity that can be machined to the desired airfoil shape may be used in some embodiments of the EHD fluid accelerator apparatus described herein.

While the techniques and implementations have been described with reference to exemplary embodiments, it will be understood by those skilled in the art that various changes may be made and equivalents may be substituted for elements thereof. In addition, many modifications may be made to adapt a particular situation or material to the teachings without departing from the essential scope thereof. Therefore, the particular embodiments, implementations and techniques disclosed herein, some of which indicate the best mode contemplated for carrying out these embodiments, implementations and techniques, are not intended to be limiting in any way.

What is claimed is:

1. An electrohydrodynamic fluid accelerator apparatus comprising
a substrate for thermal conduction therethrough; and
a plurality of electrode structures for thermal conduction therethrough; each electrode structure having a collector electrode portion and a corona discharge electrode portion.
